(19) United States
(12) Patent Application Publication
(10) Pub. No.: US 2025/0158349 A1
(43) Pub. Date: May 15, 2025

(54) LENS CURING DEVICE AND METHOD FOR MULTI-CHANNEL OPTICAL MODULE

(71) Applicant: ELECTRONICS AND TELECOMMUNICATIONS RESEARCH INSTITUTE, Daejeon (KR)

(72) Inventors: Eun Kyu KANG, Daejeon (KR); Haechung KANG, Daejeon (KR); Jong Jin LEE, Daejeon (KR); Won-Bae KWON, Daejeon (KR); Soo Yong JUNG, Daejeon (KR); Sangjin KWON, Daejeon (KR); Myunghwan KIM, Daejeon (KR)

(73) Assignee: ELECTRONICS AND TELECOMMUNICATIONS RESEARCH INSTITUTE, Daejeon (KR)

(21) Appl. No.: 18/827,421

(22) Filed: Sep. 6, 2024

(30) Foreign Application Priority Data
Nov. 9, 2023 (KR) 10-2023-0154277

(51) Int. Cl. H01S 5/02253; H01S 5/02251; H01S 5/02315; H01S 5/40

(52) U.S. Cl. CPC H01S 5/02253; H01S 5/02251; H01S 5/02315; H01S 5/4081

(57) ABSTRACT

Provided is a lens curing device for a multi-channel optical module, which cures a lens after arranging the lens on multiple axes between a laser diode and an optical waveguide of the optical module for each channel, the lens curing device including a vacuum collet that picks up the lens, a driver that moves the vacuum collet that picks up the lens and disposes the moved vacuum collet at an arrangement position of a submount, and an optical fiber that is embedded in at least a portion of the vacuum collet while connected to an ultraviolet (UV) light source in a preset wavelength band and transmits light radiated from the UV light source to a UV epoxy applied to a lower end of the lens.

### CROSS-REFERENCE TO RELATED APPLICATION

This application claims priority to and the benefit of Korean Patent Application No. 10-2023-0154277, filed on Nov. 9, 2023, the disclosure of which is incorporated herein by reference in its entirety.

### BACKGROUND

### 1. Field of the Invention

The present invention relates to a lens curing device and method for a multi-channel optical module.

### 2. Discussion of Related Art

In recent years, as data traffic has rapidly increased, an optical module (commonly referred to as an optical transmission and reception module) capable of transmitting a large amount of data at a high speed without distortion of a signal has been spotlighted.

An optical transmission module converts an electrical signal into an optical signal through a laser diode (LD). In particular, to increase optical efficiency, a lens is arranged between the laser diode and an optical waveguide and then fixed to a submount.

When the lens is fixed to the submount, ultraviolet (UV) epoxy is used to perform the fixing in a short time. However, because a shrinkage phenomenon occurs in the UV epoxy during a curing process, this may cause distortion of the lens (misalignment of light).

For example, in the related art, an ultraviolet lamp radiates light toward the UV epoxy from the outside of a vacuum collet that picks up the lens. In this process, because a space in which the lens is disposed is narrow, a non-uniform shrinkage phenomenon in which the UV light is not radiated evenly and is radiated from one direction had occurred. Accordingly, the lens was misaligned from a designated position.

Further, there is a high possibility that the light alignment of the lens may be done improperly because thermal expansion occurs due to heat generation as a metallic vacuum collet is irradiated with the UV light. This soon leads to a rework process of removing the lens and the UV epoxy of a corresponding channel. As a result, a process time is delayed, and product productivity is decreased.

### SUMMARY OF THE INVENTION

The present invention is directed to providing a lens curing device and method for a multi-channel optical module, which may simultaneously perform optical alignment of a lens and UV epoxy curing process by uniformly curing a target in position after an optical fiber is inserted into a vacuum collet.

The aspects of the present invention are not limited to the aspects described above, and those skilled in the art will clearly understand other aspects not described herein from the following description.

According to an aspect of the present invention, there is provided a lens curing device for a multi-channel optical module, which cures a lens after arranging the lens on multiple axes between a laser diode and an optical waveguide of the optical module for each channel, the lens curing device including a vacuum collet that picks up the lens, a driver that moves the vacuum collet that picks up the lens and arranges the moved vacuum collet at an arrangement position of a submount, and an optical fiber that is embedded in at least a portion of the vacuum collet while connected to an ultraviolet (UV) light source in a preset wavelength band and transmits light radiated from the UV light source to a UV epoxy applied to a lower end of the lens.

The vacuum collet may have an end that picks up the lens and has a bent structure and a center hole through which the optical fiber vertically passes may be formed only in a partial section of an upper end thereof.

The lens curing device may further include a controller that integrally controls the UV light source and the driver.

The controller may control the driver and the UV light source so that light alignment and curing of the lens are simultaneously performed.

The center hole of the vacuum collet may be concentric with a center of an arrangement position at which the lens is cured.

The vacuum collet may include a sealing member that fills a gap between the center hole and the optical fiber.

The optical fiber may include a core and a cladding surrounding the core.

The cladding may be surrounded above the center hole of the vacuum collet, and only the core may be inserted into the vacuum collet.

The optical fiber may be a single mode fiber (SMF) inserted into the vacuum collet to a preset depth.

The optical fiber may be a multi-mode fiber (MMF) inserted into the vacuum collet to a preset depth.

The UV light source may have a wavelength band of 200 nm to 400 nm.

The lens curing device may further include a fixing piece fitted into an input side of the vacuum collet while surrounding a core of the optical fiber and having a hollow shape.

The fixing piece may include a holder surrounding the core of the optical fiber, and a connection cap extending outward from an edge of the holder and detachably attached to an input side of the vacuum collet.

The lens curing device may further include a plurality of elastic members that pass through the vacuum collet in a longitudinal direction and protect a core of the optical fiber.

The vacuum collet and the optical fiber may simultaneously perform light alignment and curing of the lens.

The vacuum collet may include a first pipe having a first vacuum hole and a second pipe that has a second vacuum hole communicating with the first vacuum hole and is a section in which the lens is picked up.

The first pipe and the second pipe may have a bent structure.

The first pipe may include a center hole formed in a partial section of an upper end thereof such that the optical fiber vertically passes therethrough.

The second pipe may include a plurality of side holes through which the plurality of elastic members are formed to pass.

The second pipe may include a finishing holder surrounding the plurality of sides holes through which the plurality of elastic members pass.

The vacuum collet may include a sealing member that fills a gap between the center hole and the optical fiber.

According to another aspect of the present invention, there is provided a lens curing device for a multi-channel optical module, which cures a lens after arranging the lens on multiple axes between a laser diode and an optical waveguide of the optical module for each channel, the lens curing device including a vacuum collet having an adhesive member that adheres and picks up the lens, a driver that moves the vacuum collet and arrange the moved vacuum collet at an arrangement position of a submount, and an optical fiber that is embedded in at least a portion of the vacuum collet while connected to an ultraviolet (UV) light source in a preset wavelength band and transmits light radiated from the UV light source to a UV epoxy applied to a lower end of the lens.

The adhesive member may include polydimethylsiloxane (PDMS) that is a transparent material that allows UV light to be transmitted.

According to still another aspect of the present invention, there is provided a lens curing method for a multi-channel optical module, in which a lens is cured after arranging the lens on multiple axes between a laser diode and an optical waveguide of the optical module for each channel, the lens curing method including an operation (first operation) of picking up the lens through a vacuum collet into which an optical fiber connected to an ultraviolet (UV) light source in a preset wavelength band is inserted, an operation (second operation) of applying a certain amount of a UV epoxy to a lower end of the picked-up lens and moving the lens to an arrangement position of a submount, an operation (third operation) of radiating UV light toward the UV epoxy applied to the lower end of the lens in a state in which the lens is disposed in the arrangement position, and an operation (fourth operation) of monitoring an output state of the UV light.

In the first operation, the optical fiber may be a multi-mode fiber (MMF) inserted into the vacuum collet to a preset depth.

In the second operation, the arrangement position may be a preset setting position at which the lens is disposed on multiple axes between a laser diode and an optical waveguide of the optical module for each channel.

In the fourth operation, when output power of the UV light is less than a reference value, a position of the lens may be corrected, and when it is difficult to correct the position of the lens, a rework is performed after the lens and the UV epoxy are removed from the arrangement position.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is an exemplary view illustrating a multi-channel optical module according to the present invention;

FIG. 2 is an exemplary view illustrating an operation of a lens curing device through cross section A-A′ illustrated in FIG. 1 according to a first embodiment of the present invention;

FIGS. 3A and 3B are an exemplary view illustrating an optical fiber in a lens curing device according to the first embodiment of the present invention;

FIG. 4 is a schematic exemplary view illustrating a driving mechanism of the lens curing device according to the first embodiment of the present invention;

FIG. 5 is an exemplary view illustrating a configuration of a lens curing device according to a second embodiment of the present invention;

FIG. 6 is a schematic exemplary view illustrating a driving mechanism of the lens curing device according to the second embodiment of the present invention;

FIG. 7 is an exemplary view illustrating a portion of a lens curing device according to a third embodiment of the present invention;

FIG. 8 is an exemplary view illustrating an operation of the lens curing device through cross section B-B′ illustrated in FIG. 7 according to the third embodiment of the present invention;

FIG. 9 is an exemplary view illustrating a portion of a lens curing device according to a fourth embodiment of the present invention;

FIG. 10 is an exemplary view illustrating an operation of the lens curing device through cross section C-C′ illustrated in FIG. 9 according to the fourth embodiment of the present invention;

FIG. 11 is an exemplary view illustrating a portion of a lens curing device according to a fifth embodiment of the present invention;

FIG. 12 is an exemplary view illustrating an operation of the lens curing device through cross section D-D′ illustrated in FIG. 11 according to the fifth embodiment of the present invention;

FIG. 13 is a block diagram illustrating a configuration of a controller for implementing a lens curing device for the multi-channel optical module according to the present invention; and

FIG. 14 is a flowchart illustrating a lens curing method for the multi-channel optical module according to the present invention.

### DETAILED DESCRIPTION OF EXEMPLARY EMBODIMENTS

Advantages and features of the present invention and a method of achieving the advantages and the features will become apparent with reference to embodiments described below in detail together with the accompanying drawings. However, the present invention is not limited to the embodiments disclosed below and may be implemented in various different forms. The present embodiments are merely provided to complete the disclosure of the present invention and fully inform those skilled in the art to which the present invention pertains of the scope of the present invention, and the present invention is defined by the description of the appended claims. Meanwhile, terms used in the present specification are intended to describe the embodiments and are not intended to limit the present invention. In the specification, a singular form also includes a plural form unless specifically mentioned in a phrase. The term “comprise” or “comprising” used herein does not exclude the presence or addition of one or more other components, steps, operations, and/or elements in addition to the mentioned components, steps, operations, and/or elements. In the present specification, the term “and/or” includes any one or all possible combinations of the listed items.

Configurations of each embodiment may have the same shape, the same function, and the same effect as duplicate configurations (even when reference numerals are different, when the configurations are the same in the description and the drawings, the configurations are the same) unless differences are specifically highlighted or indicated. Further, a lens curing method may be applied to all embodiments of a lens curing device.

Hereinafter, exemplary embodiments of the present invention will be described in detail with reference to the accompanying drawings.

### [Lens Curing Device for Multi-Channel Optical Module]

### Basic Embodiment (First Embodiment)

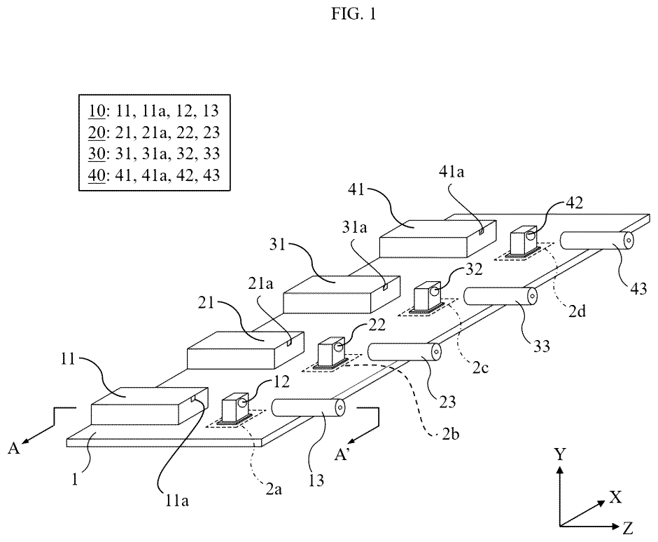

FIG. 1 illustrates a multi-channel optical module according to the present invention.

In multi-channel optical modules 10, 20, 30, and 40, for each channel, lenses 12, 22, 32, and 42 may be arranged between laser diodes 11, 21, 31, and 41 and optical waveguides 13, 23, 33, and 43 on multiple axes (e.g., three axes, six axes, or the like), and at the same time, may be cured. Therefore, the multi-channel optical modules 10, 20, 30, and 40 may prevent or minimize distortion of the lenses 12, 22, 32, and 42 due to a shrinkage phenomenon of an ultraviolet (UV) epoxy 3.

The multi-channel optical modules 10, 20, 30, and 40 have a form in which light emitted from light emitting units 11a, 21a, 31a, and 41a passes through the lenses 12, 22, 32, and 42 and is focused on the optical waveguides 13, 23, 33, and 43. In this case, the light emitting units 11a, 21a, 31a, and 41a are located at uppermost ends of the laser diodes 11, 21, 31, and 41 mounted on a submount 1.

In manufacturing the multi-channel optical modules 10, 20, 30, and 40, integration of a multi-channel optical system including the laser diodes 11, 21, 31, and 41, the lenses 12, 22, 32, and 42, and the optical waveguides 13, 23, 33, and 43 for each channel is an important factor that affects mass production and a yield rate.

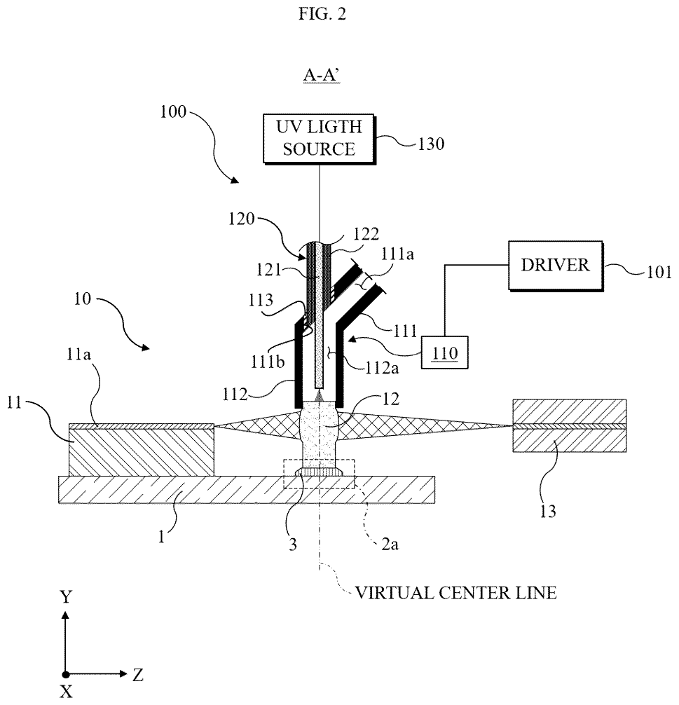

The optical module having four channels of FIG. 1 is illustrated, but the present invention is not limited thereto. For example, the multi-channel optical module of the present invention may include eight channels at 100 Gbps by applying a 4 level pulse amplitude modulation (PAM-4) technology. Further, in the present invention, even when eight channels or more are implemented, lenses (not illustrated) having various shapes mounted on the submount 1 for each channel are optically aligned, at the same time, the UV epoxy 3 (see FIG. 2) is uniformly cured, and thus a process time may be dramatically decreased.

FIG. 2 illustrates a basic configuration and an operation example of the lens curing device through cross section A-A′ illustrated in FIG. 1 according to a first embodiment of the present invention.

A lens curing device 100 according to the first embodiment of the present invention includes a vacuum collet 110, a driver 101, and an optical fiber 120.

The vacuum collet 110 vacuum-suctions and picks up the lens 12.

The vacuum collet 110 includes a first pipe 111, a second pipe 112, and a sealing member 113.

The first pipe 111 includes a first vacuum hole 111a and a center hole 111b formed in a partial section of an upper end thereof such that the optical fiber 120 vertically passes therethrough.

It is preferable that the center hole 111b of the vacuum collet 110 be concentric with a center of an arrangement position 2a.

The second pipe 112 has a second vacuum hole 112a that communicates with the first vacuum hole 111a. The second pipe 112 is a section in which the lens 12 is picked up.

The first pipe 111 and the second pipe 112 have a bent structure.

The sealing member 113 fills a gap between the center hole 111b and the optical fiber 120. An inner surface of the sealing member 113 surrounds a circumferential surface of the optical fiber 120, and an outer surface of the sealing member 113 is fitted onto an inner surface of the center hole 111b. The outer surface of the sealing member 113 may have a structure that enables snap-fit connection with the inner surface of the center hole 111b.

The driver 101 moves the vacuum collet 110 that picks up the lens 12 and arranges the moved vacuum collet 110 at the arrangement position 2a of the submount 1.

The driver 101 may control not only the movement of the vacuum collet 110 but also an ON/OFF operation and various functions of the vacuum collet 110.

Light radiates toward the UV epoxy 3 through the optical fiber 120 inserted into the vacuum collet 110. The optical fiber 120 is connected to a UV light source 130 having a wavelength of 200 nm to 400 nm and serves to transmit the UV light to the arrangement position 2a. Here, the arrangement position 2a may be a preset setting position at which the lens 12 is arranged between the laser diode 11 and the optical waveguide 13 on multiple axes (e.g., three axes, six axes, or the like). In this case, the optical fiber 120 may be a single mode optical fiber (SMF) or a multi-mode optical fiber (MMF).

The optical fiber 120 has a structure that includes a core 121 and a cladding 122 surrounding the core 121. The cladding 122 is surrounded above the center hole 111b of the vacuum collet 110, and the core 121 is inserted into the vacuum collet 110 through the center hole 111b. Here, in the optical fiber 120, it is preferable that only the core 121 be inserted into the vacuum collet 110. This is because the first and second vacuum holes 111a and 112a of the vacuum collet 110 have a small size of about 300 μm to 400 μm in diameter. This is also because the pickup (vacuum-suction) operation of the vacuum collet 110 may be smoothly performed only when a meaningful separation space is secured between the core 121 and the second vacuum hole 112a of the vacuum collet 110.

When the optical fiber 120 is vertically inserted into and passes through the vacuum collet 110, light radiates through the optical fiber 120 toward a central portion of the lens 12 seated at the arrangement position 2a based on a virtual center line to uniformly cure the UV epoxy 3 within a reference time. Here, a curing reference time may be determined based on accumulated experimental results according to various conditions. The virtual center line may be a center point of the arrangement position 2a.

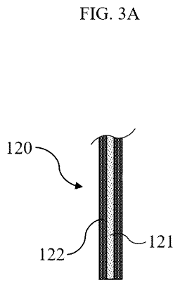

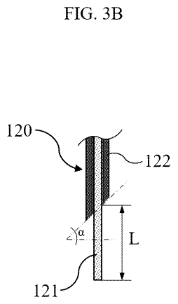

FIGS. 3A and 3B are a view for describing the optical fiber in the lens curing device according to the first embodiment of the present invention.

The optical fiber 120 is a type of thin glass or plastic fiber that transmits optical signals, and can transmit a larger amount of data over a longer distance than a copper wire. In this case, the optical fiber 120 used as a glass fiber has less data loss and less electromagnetic interference and withstands a higher temperature than a metal.

In the optical fiber 120, a refractive index of the cladding 122 that prevents light from leaking to the outside is smaller than a refractive index of the core 121, and thus the light input into the core 121 propagates by repeating total reflection at an interface between the core 121 and the cladding 122 having different refractive indexes.

When the optical fiber 120 is inserted into the center hole 111b of the vacuum collet 110 (see FIG. 1), a portion of the optical fiber 120 is cut so as not to block a vacuum hole of the vacuum collet 110 (see FIG. 1), and then only the core 121 may be inserted thereinto. In this case, because the vacuum collet 110 (see FIG. 1) has a bent structure having an inclination, it is preferable that the cladding 122 be cut at an angle a corresponding to the bent structure.

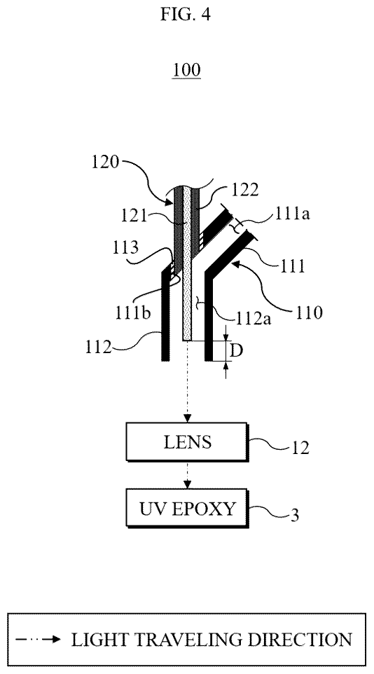

FIG. 4 schematically illustrates a driving mechanism of the lens curing device according to the first embodiment of the present invention.

It is preferable that the optical fiber 120 be inserted into the vacuum collet 110 to a preset depth D. More precisely, it is preferable that the core 121 of the optical fiber 120 be inserted to the preset depth D. In this case, the preset depth D may be determined in consideration of a space required between the optical fiber 120 and the lens 12, an input angle, or the like.

The optical fiber 120 allows the UV light received from the UV light source 130 (see FIG. 1) to be radiated to the UV epoxy 3 through the central portion of the lens 12 seated on an arrangement position. Therefore, a central portion of the UV epoxy 3 is first cured to prevent misalignment of the lens 12.

### Modified Embodiments (Second Embodiment to Fifth Embodiment)

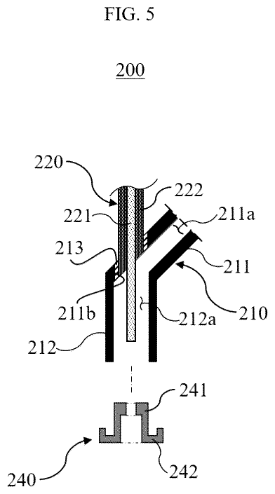

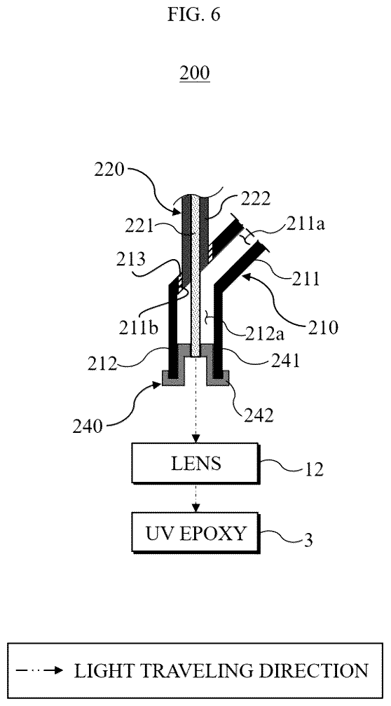

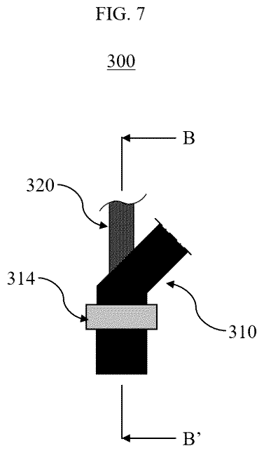

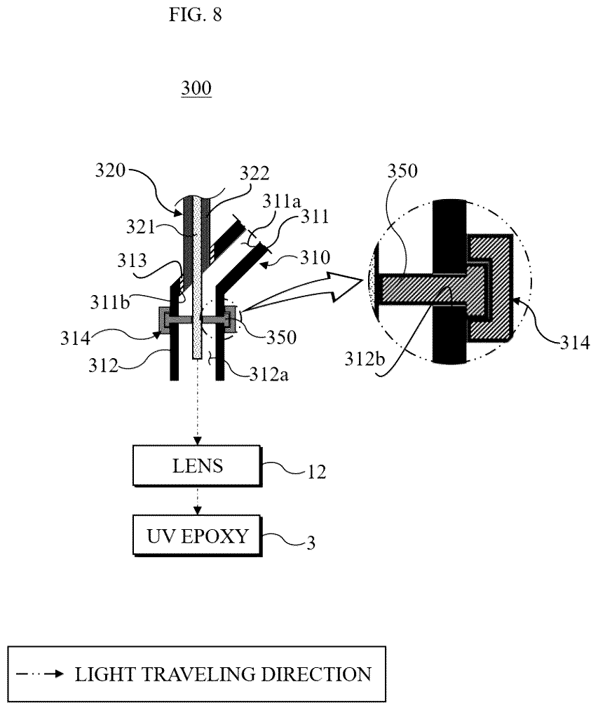

FIG. 5 is an exemplary view illustrating a configuration of a lens curing device according to a second embodiment of the present invention, and FIG. 6 is a schematic exemplary view illustrating a driving mechanism of the lens curing device according to the second embodiment of the present invention.

A lens curing device 200 according to the second embodiment additionally includes a fixing piece 240 based on the first embodiment.

The fixing piece 240 is fitted into an input side (second pipe) 212 of a vacuum collet 210 while surrounding a core 221 of an optical fiber 220 and has a hollow shape.

The fixing piece 240 includes a holder 241 and a connection cap 242.

The holder 241 surrounds the core 221 of the optical fiber 220. In this case, the holder 241 may have an inner diameter corresponding to the core 221.

The connection cap 242 may have a structure that extends outward from an edge of the holder 241 and may be detachably attached to the second pipe 212 of the vacuum collet 210.

The fixing piece 240 may have an integrated structure in which the holder 241 and the connection cap 242 are integrally formed or may have a separate structure in which one of the holder 241 and the connection cap 242 is partially fitted into the other.

Because the connection cap 242 is fitted into the input side of the second pipe 212 and the holder 241 partially surrounds the core 221, the fixing piece 240 can maintain durability of the core 221 through which the UV light radiates.

FIG. 7 is an exemplary view illustrating a portion of a lens curing device according to a third embodiment of the present invention, and FIG. 8 is an exemplary view illustrating an operation of the lens curing device through cross section B-B′ illustrated in FIG. 7 according to the third embodiment of the present invention.

A lens curing device 300 according to the third embodiment additionally includes a finishing holder 314 and an elastic member 350 based on the first embodiment to maintain durability of a core 321.

A second pipe 312 of a vacuum collet 310 may have a plurality of side holes 312b formed in a partial circumferential surface (side surface) thereof.

The elastic member 350 is forcibly fitted into the side hole 312b. A plurality of elastic members 350 may be coupled to the side holes 312b while forcibly fitted thereinto. As another example, the elastic member 350 may have the form of a plurality of arms (not illustrated) fitted into the side holes 312b and a rim (not illustrated) that connects the arms and may be opened or closed.

The finishing holder 314 may be made of an elastic material and may have a form that surrounds the plurality of side holes 312b through which the plurality of elastic members 350 pass.

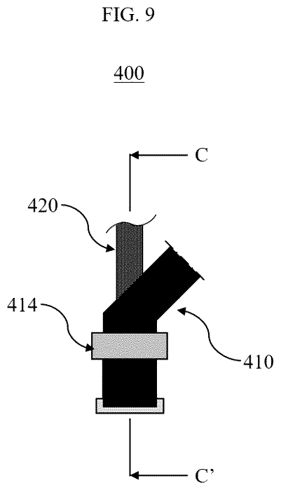

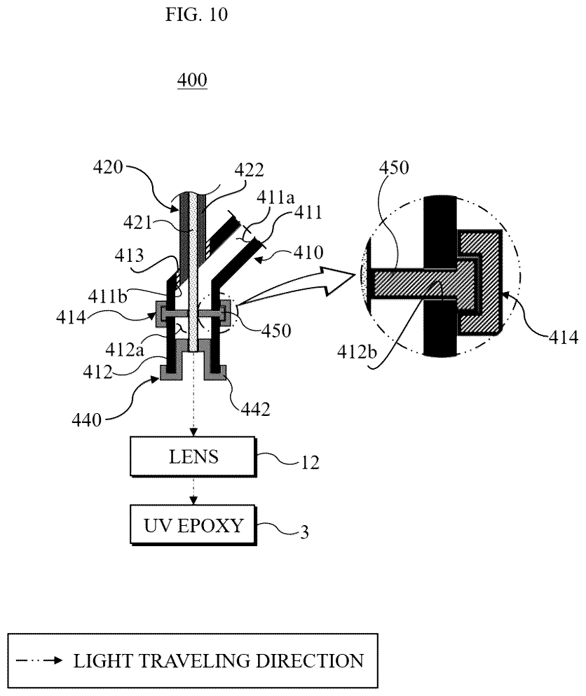

FIG. 9 is an exemplary view illustrating a portion of a lens curing device according to a fourth embodiment of the present invention, and FIG. 10 is an exemplary view illustrating an operation of the lens curing device through cross section C-C′ illustrated in FIG. 9 according to the fourth embodiment of the present invention.

A lens curing device 400 according to the fourth embodiment may be configured by combining the second embodiment and the third embodiment based on the first embodiment to maintain durability of a core 421.

That is, the lens curing device 400 according to the fourth embodiment additionally includes a fixing piece 440 that is additionally configured in the second embodiment and a finishing holder 414 and an elastic member 450 that are additionally configured in the third embodiment based on the first embodiment.

The core 421 may maintain durability while smoothly receiving the UV light from the UV light source and radiating light to a target position (arrangement position), through a combination of the fixing piece 440, the holder 414, and the elastic member 450.

Because the fixing piece 440, the holder 414, and the elastic member 450 have a structure that is easily attached or detached even when the fixing piece 440, the holder 414, and the elastic member 450 are worn, the fixing piece 440, the holder 414, and the elastic member 450 may be replaced at any time.

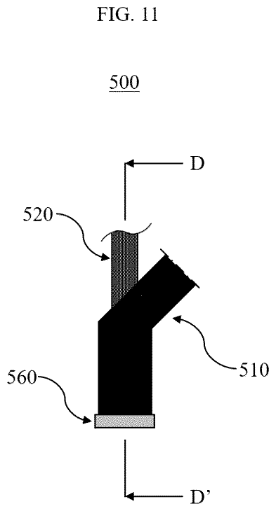

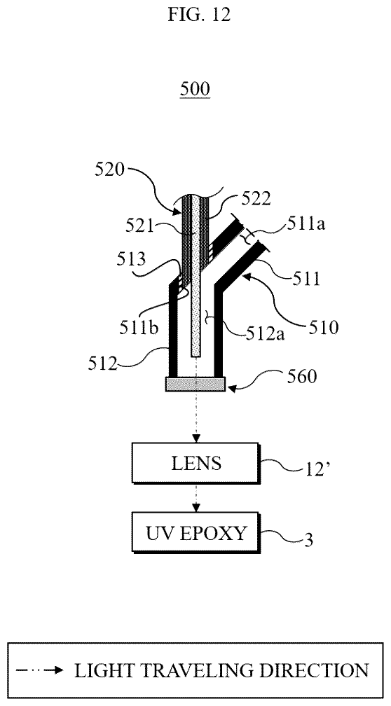

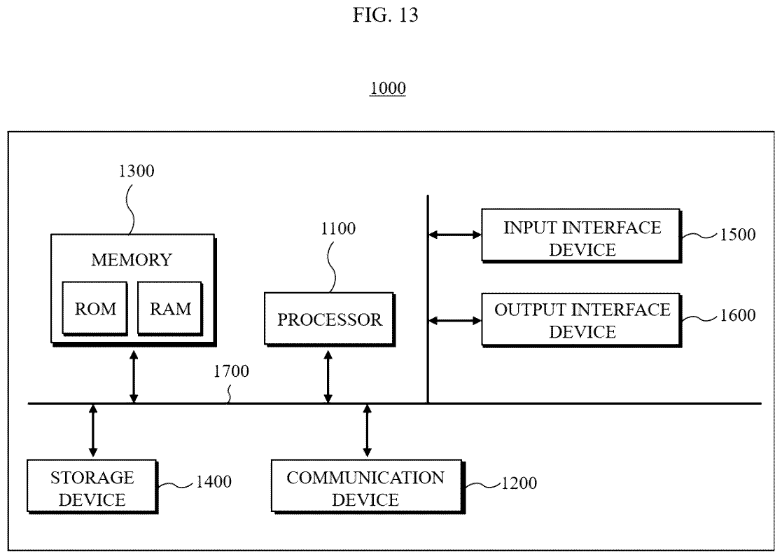

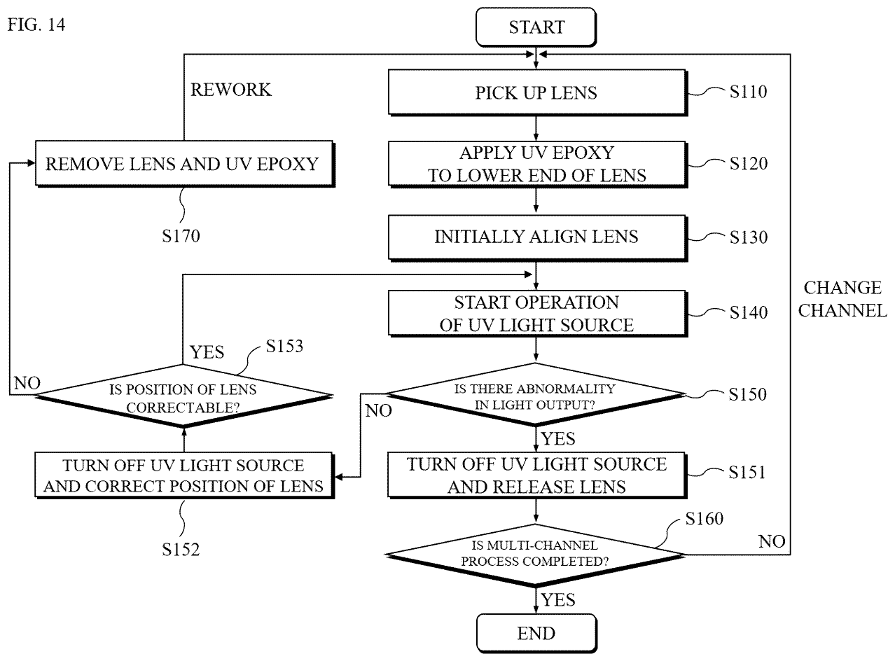

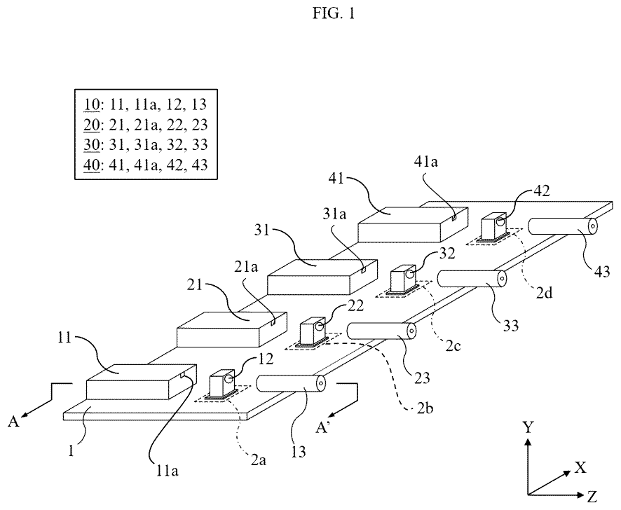

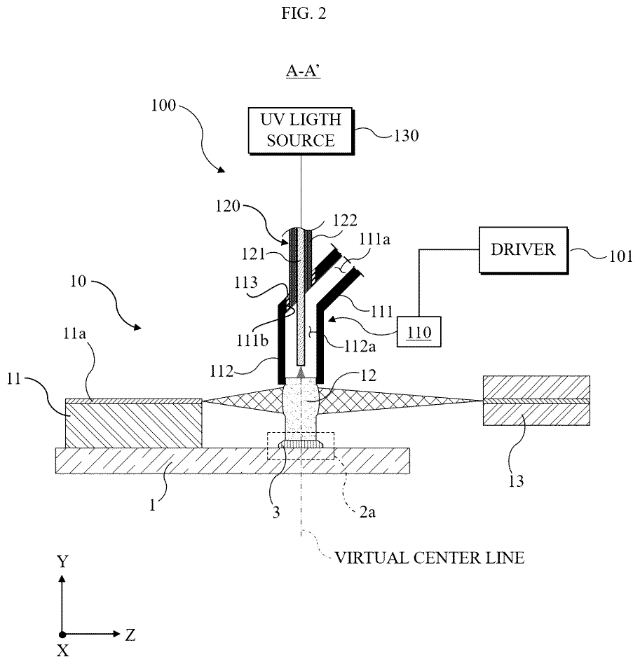

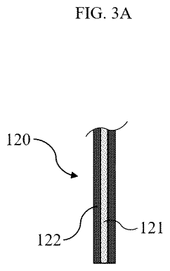

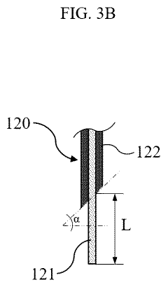

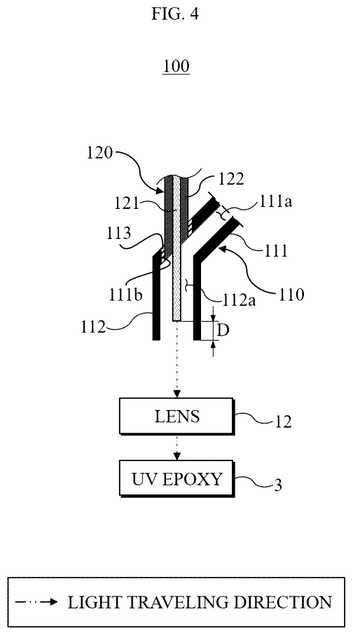

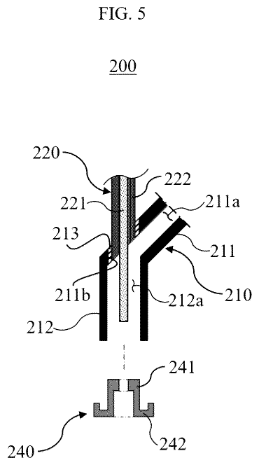

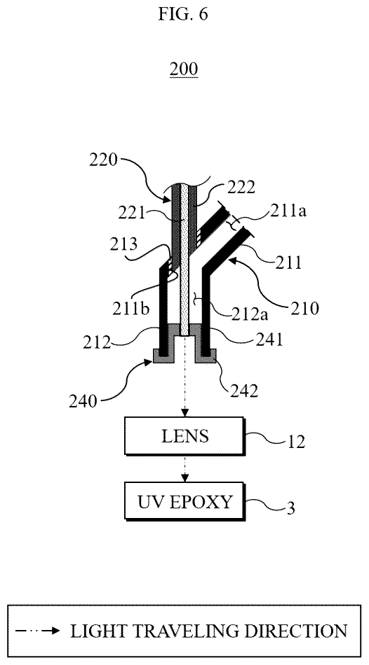

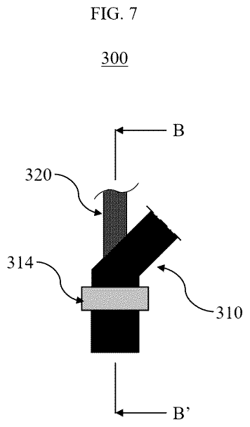

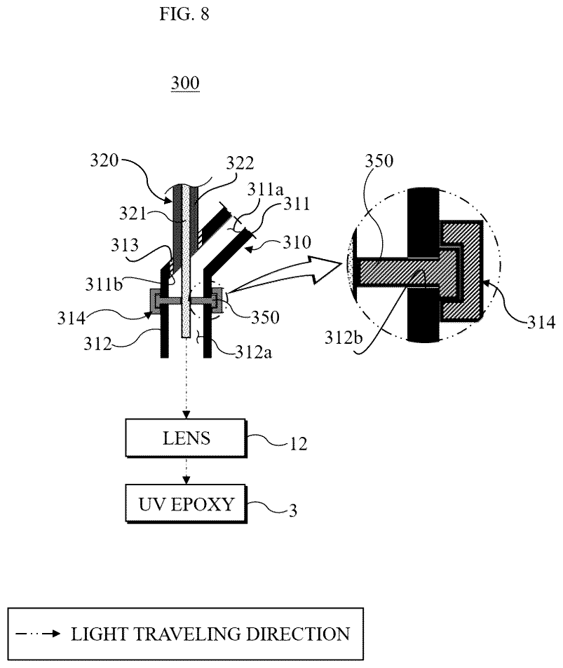

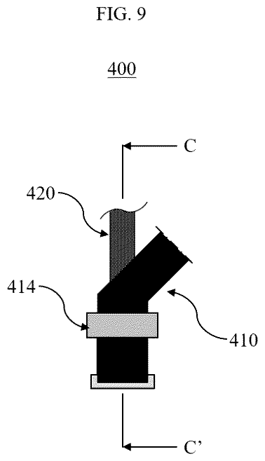

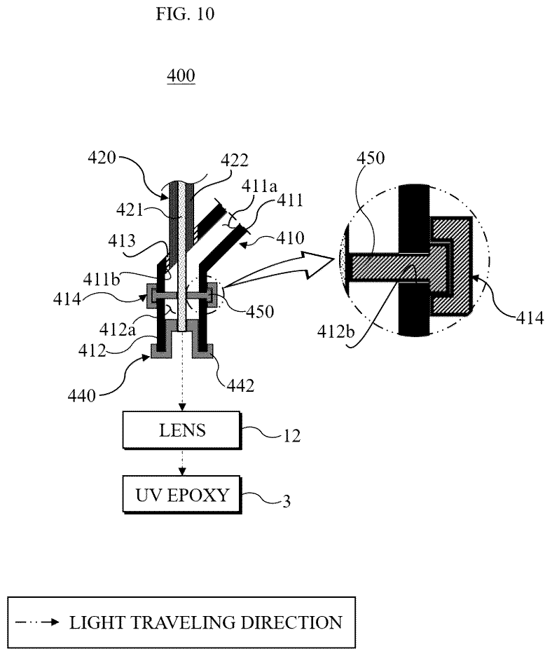

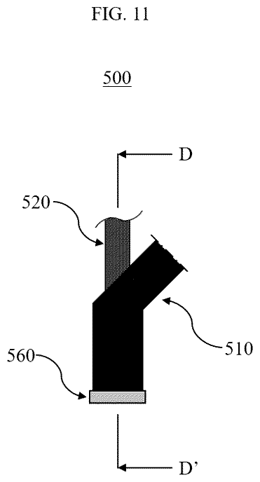

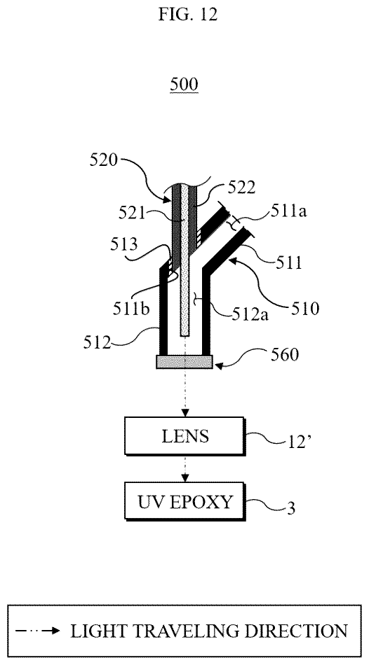

FIG. 11 is an exemplary view illustrating a portion of a lens curing device according to a fifth embodiment of the present invention, and FIG. 12 is an exemplary view illustrating an operation of the lens curing device through cross section D-D′ illustrated in FIG. 11 according to the fifth embodiment of the present invention.

Referring to FIGS. 11 and 12, a lens curing device 500 for the multi-channel optical module includes a vacuum collet 510 and an optical fiber 520.

The lens curing device 500 according to the fifth embodiment includes an adhesive member 560 based on the first embodiment.

The adhesive member 560 may be located on an input side of the vacuum collet 510 and serve to adhere and simply pick up a lens 12′. That is, the adhesive member 560 may adhere the lens 12′ and then simply pick up the lens 12′. In this case, the lens 12′ may be a quadrangular lens.

The adhesive member 560 may be made of polydimethylsiloxane (PDMS) that is a transparent material capable of transmitting UV light.

### Configuration Applied to all Embodiments (Controller)

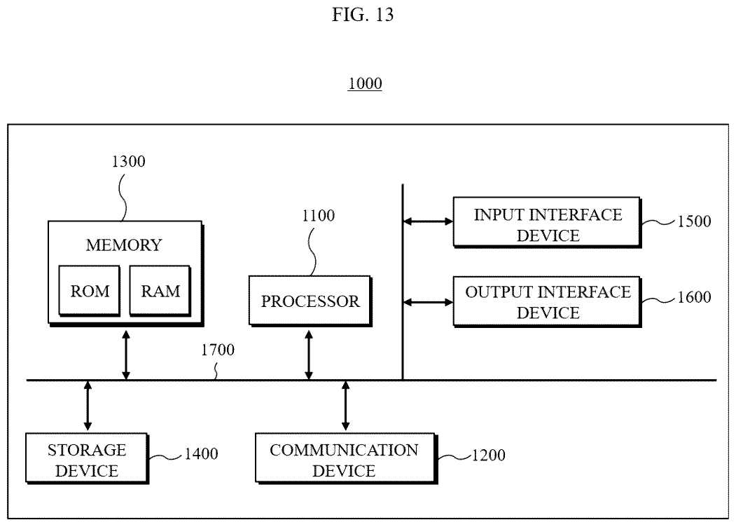

FIG. 13 is a block diagram illustrating a configuration of a controller for implementing a lens curing device for the multi-channel optical module according to the present invention.

A controller 1000 is a computer system and manages the overall operations of the lens curing devices 100, 200, 300, 400, and 500 according to the present invention. For example, the controller 1000 may integrally control the UV light source 130 (see FIG. 2) and the driver 101 (see FIG. 2) to simultaneously perform light alignment and curing of the lens.

The controller 1000 may include at least one of a processor 1100, a memory 1300, an input interface device 1500, an output interface device 160, and a storage device 1400 that communicate with each other through a bus 1700. The controller 1000 may also include a communication device 1200 coupled to a network.

The processor 1100 executes a program stored in the memory 1300.

The processor 1100 may be at least one of a central processing unit (CPU) and/or a graphics processing unit (GPU) or a semiconductor device that executes commands stored in the memory 1300 or the storage device 1400.

The processor 1100 may include a CPU, a GPU, a system-on-chip, a microcontroller unit (MCU), or the like configured to control and manage the overall operations of the present invention.

The communication device 1200 may transmit or receive a wired signal or a wireless signal.

The memory 1300 and the storage device 1400 are various types of volatile or non-volatile storage media, and for example, the memory 1300 may include a read-only memory (ROM) or a random access memory (RAM). In the embodiment of the present disclosure, the memory 1300 may be located inside or outside the processor 1100, and the memory 1300 may be connected to the processor 1100 through various previously known methods.

For example, the input/output interfaces 1500 and 1600 may transmit commands or data input by a user or other external devices to other component(s) of the lens curing devices 100, 200, 300, and 400 or may output commands and data received from the other component(s) of the lens curing device 100, 200, 300, and 400 to the user or the other external devices.

Further, a method according to the embodiment of the present invention may be implemented in the form of program commands that may be performed through various computer units and recorded on a computer-readable recording medium. Here, the computer-readable recording medium may include program commands, data files, data structures, and the like alone or in combination.

The program commands recorded on the computer-readable recording medium may be specially designed for the embodiments of the present invention or may be known and usable by those skilled in the computer software field.

The computer-readable recording medium may include a hardware device configured to store and perform the program commands. For example, the computer-readable recording medium may include magnetic media such as hard disks, floppy disks, and magnetic tapes, optical media such as compact disc read-only memories (CD-ROMs) and digital versatile discs (DVDs), magneto-optical media such as a floptical disk, a ROM, a RAM, a flash memory, or the like. The program commands may include not only a machine language code that may be created by a compiler but also a high-level language code that may be executed by a computer through an interpreter or the like.

### [Lens Curing Method for Multi-Channel Optical Module]

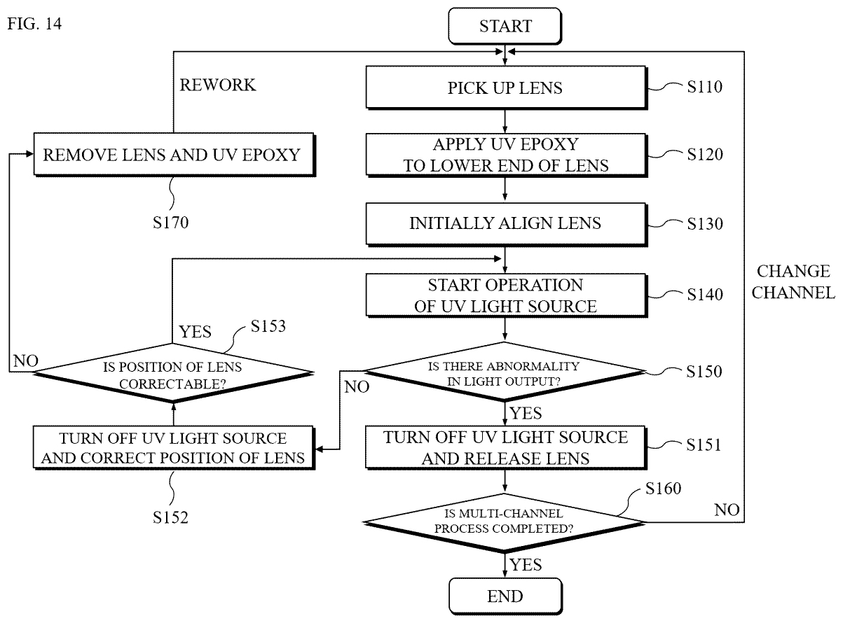

FIG. 14 is a flowchart illustrating a lens curing method for the multi-channel optical module according to the present invention.

The lens curing method for the multi-channel optical module roughly includes a lens pickup operation S110, a UV epoxy application operation S120, an initial lens alignment operation S130, a UV light source operation start operation S140, a light output monitoring operation S150, a multi-channel process completion identification operation S160, and a rework operation S170.

In the lens pickup operation S110, a lens is picked up through a vacuum collet into which an optical fiber is inserted. In this case, a core of the optical fiber may be an SMF or an MMF in which the core is inserted into the vacuum collet to a preset depth.

In the UV epoxy application operation S120, a lower end of the picked-up lens is coated with a certain amount of the UV epoxy.

In the initial lens alignment operation S130, the vacuum collet that picks up the lens coated with the UV epoxy moves to an arrangement position of the submount using a driver. Here, it is preferable that the arrangement position be a preset setting position at which the lens is disposed on multiple axes between a laser diode and an optical waveguide of the optical module for each channel.

In the UV light source operation start operation S140, light radiates toward the UV epoxy inside the vacuum collet through the optical fiber, and thus the lens is disposed at the arrangement position, and at the same time, is cured. That is, the lens moves to the arrangement position, and at the same time, the optical fiber uniformly cures the UV epoxy (S140).

In the light output monitoring operation S150, it is determined whether a digital signal representing the position of the lens in a system exceeds a certain range or is continuously displaced, and the determination is performed by a system program based on an algorithm.

In this operation, when there is no abnormality in the light output, the UV light source is turned off, and the lens is released (S151).

Thereafter, after it is identified whether the multi-channel process is completed (S160), when the multi-channel process is uncompleted, the work proceeds to the lens pickup operation S110 through changing of a channel. When the multi-channel process is completed, the work is completed.

When an abnormality occurs in the light output, operation S152 of turning off the UV light source and correcting the position of the lens is performed. In this case, it is identified whether the position of the lens is correctable (S153). When the curing of the UV epoxy has greatly progressed, the lens correction work is impossible, and thus a rework is performed, and when the position of the lens is correctable, the work proceeds back to the UV light source operation start operation S140.

The rework operation S170 is an operation of performing a rework of removing the lens and the UV epoxy when it is determined that the lens is unfixed to a correct position. However, in the present invention, the optical fiber is inserted into the vacuum collet, light accurately radiates toward the central portion of the lens through the optical fiber, curing starts from the central portion of the UV epoxy, and thus the rework operation may hardly progress.

According to the present invention, light radiates toward a UV epoxy via a center of the lens through an optical fiber inserted into a vacuum collet from an upper center of a lens moved to an arrangement position, and thus light alignment of the lens and a UV epoxy curing process can be simultaneously performed.

In this process, the light may locally radiate toward a target position (lens arrangement position) inside the vacuum collet through the optical fiber, and thus misalignment of the light alignment due to a thermal expansion problem in the related art can be minimized.

In particular, in a multi-channel process, the same process condition is applied to each channel, and thus an automated process can be effectively performed. As a result, the light alignment and the UV epoxy curing time are dramatically decreased, and thus productivity can be improved, and process times can be decreased.

Although the configuration of the present invention has been described above in detail through exemplary embodiments, this is merely an example, and it is obvious that various modifications and changes may be made within the scope in which the technical spirit of the present invention is permitted.

Thus, the scope of protection of the present invention should be determined from the appended claims.

What is claimed is:

1. A lens curing device for a multi-channel optical module, which cures a lens after arranging the lens on multiple axes between a laser diode and an optical waveguide of the optical module for each channel, the lens curing device comprising:
a vacuum collet configured to pick up the lens;
a driver configured to move the vacuum collet configured to pick up the lens and arrange the moved vacuum collet at an arrangement position of a submount; and
an optical fiber embedded in at least a portion of the vacuum collet while connected to an ultraviolet (UV) light source in a preset wavelength band and configured to transmit light radiated from the UV light source to a UV epoxy applied to a lower end of the lens,
wherein the vacuum collet has an end configured to pick up the lens and having a bent structure and a center hole through which the optical fiber vertically passes is formed only in a partial section of an upper end thereof.

2. The lens curing device of claim 1, further comprising a controller configured to integrally control the UV light source and the driver,
wherein the controller controls the driver and the UV light source so that light alignment and curing of the lens are simultaneously performed.

3. The lens curing device of claim 1, wherein the center hole of the vacuum collet is concentric with a center of an arrangement position at which the lens is cured.

4. The lens curing device of claim 1, wherein the vacuum collet includes a sealing member that fills a gap between the center hole and the optical fiber.

5. The lens curing device of claim 1, wherein the optical fiber includes:
a core; and
a cladding surrounding the core, and
the cladding is surrounded above the center hole of the vacuum collet, and only the core is inserted into the vacuum collet.

6. The lens curing device of claim 1, wherein the optical fiber is a single mode fiber (SMF) inserted into the vacuum collet to a preset depth.

7. The lens curing device of claim 1, wherein the optical fiber is a multi-mode fiber (MMF) inserted into the vacuum collet to a preset depth.

8. The lens curing device of claim 1, wherein the UV light source has a wavelength band of 200 nm to 400 nm.

9. The lens curing device of claim 1, further comprising a fixing piece fitted into an input side of the vacuum collet while surrounding a core of the optical fiber and having a hollow shape.

10. The lens curing device of claim 9, wherein the fixing piece includes:
a holder surrounding the core of the optical fiber; and
a connection cap extending outward from an edge of the holder and detachably attached to an input side of the vacuum collet.

11. The lens curing device of claim 1, further comprising a plurality of elastic members that pass through the vacuum collet in a longitudinal direction and protect a core of the optical fiber.

12. The lens curing device of claim 11, wherein the vacuum collet includes a first pipe having a first vacuum hole and a second pipe that has a second vacuum hole communicating with the first vacuum hole and is a section in which the lens is picked up, and
the first pipe and the second pipe have a bent structure.

13. The lens curing device of claim 12, wherein the first pipe includes a center hole formed in a partial section of an upper end thereof such that the optical fiber vertically passes therethrough, and
the second pipe includes a plurality of side holes through which the plurality of elastic members are formed to pass.

14. The lens curing device of claim 13, wherein the second pipe includes a finishing holder surrounding the plurality of sides holes through which the plurality of elastic members pass.

15. The lens curing device of claim 13, wherein the vacuum collet includes a sealing member that fills a gap between the center hole and the optical fiber.

16. A lens curing device for a multi-channel optical module, which cures a lens after arranging the lens on multiple axes between a laser diode and an optical waveguide of the optical module for each channel, the lens curing device comprising:
a vacuum collet having an adhesive member configured to adhere and pick up the lens;
a driver configured to move the vacuum collet and arrange the moved vacuum collet at an arrangement position of a submount; and
an optical fiber embedded in at least a portion of the vacuum collet while connected to an ultraviolet (UV) light source in a preset wavelength band and configured to transmit light radiated from the UV light source to a UV epoxy applied to a lower end of the lens,
wherein the adhesive member includes polydimethylsiloxane (PDMS) that is a transparent material that allows UV light to be transmitted.

17. A lens curing method for a multi-channel optical module, in which a lens is cured after arranging the lens on multiple axes between a laser diode and an optical waveguide of the optical module for each channel, the lens curing method comprising:
an operation (first operation) of picking up the lens through a vacuum collet into which an optical fiber connected to an ultraviolet (UV) light source in a preset wavelength band is inserted;
an operation (second operation) of applying a certain amount of a UV epoxy to a lower end of the picked-up lens and moving the lens to an arrangement position of a submount;
an operation (third operation) of radiating UV light toward the UV epoxy applied to the lower end of the lens in a state in which the lens is disposed at the arrangement position; and
an operation (fourth operation) of monitoring an output state of the UV light.

18. The lens curing method of claim 17, wherein, in the first operation, the optical fiber is a multi-mode fiber (MMF) inserted into the vacuum collet to a preset depth.

19. The lens curing method of claim 17, wherein, in the second operation, the arrangement position is a preset setting position at which the lens is disposed on multiple axes between a laser diode and an optical waveguide of the optical module for each channel.

20. The lens curing method of claim 17, wherein, in the fourth operation, when output power of the UV light is less than a reference value, a position of the lens is corrected, and
when it is difficult to correct the position of the lens, a rework is performed after the lens and the UV epoxy are removed from the arrangement position.
